(19) United States
(12) Patent Application Publication
(10) Pub. No.: US 2013/0026535 A1
(43) Pub. Date: Jan. 31, 2013

(54) FORMATION OF INTEGRAL COMPOSITE PHOTON ABSORBER LAYER USEFUL FOR PHOTOACTIVE DEVICES AND SENSORS

(71) Applicants: Robert V. Fox, Idaho Falls, ID (US); Rene G. Rodriguez, Pocatello, ID (US); Joshua J. Pak, Pocatello, ID (US)

(72) Inventors: Robert V. Fox, Idaho Falls, ID (US); Rene G. Rodriguez, Pocatello, ID (US); Joshua J. Pak, Pocatello, ID (US)

(73) Assignee: BATTELLE ENERGY ALLIANCE, LLC, Idaho Falls, ID (US)

(21) Appl. No.: 13/191,062

(22) Filed: Jul. 26, 2011

(51) Int. Cl. H01L 33/30; H01L 27/14; H01L 31/18; B82Y 99/00

(52) U.S. Cl. 257/103; 438/95; 257/431; 977/773; 257/E31.027; 257/E33.022; 257/E27.122

(57) ABSTRACT

Methods of forming photoactive devices include infiltrating pores of a solid porous ceramic material with a fluid, which may be a supercritical fluid, carrying at least one single source precursor therein. The single source precursor may be decomposed to form a plurality of particles within the pores of the solid porous ceramic material. Photoactive devices include a solid porous ceramic material exhibiting electrical conductivity, and a plurality of photoactive semiconductor particles within pores of the solid porous ceramic material.

### CROSS-REFERENCE TO RELATED APPLICATIONS

The subject matter of this application is related to the subject matter of U.S. patent application Ser. No. 12/646,474, filed Dec. 23, 2009 in the name of Fox et al., and to the subject matter of U.S. patent application Ser. No. 12/047,956, filed Mar. 13, 2008 in the name of Fox et al., the disclosure of each of which application is incorporated herein in its entirety by this reference.

### GOVERNMENT RIGHTS

This invention was made with government support under Contract No. DE-AC07-05ID14517 awarded by the United States Department of Energy. The government has certain rights in the invention.

### TECHNICAL FIELD

Embodiments of the disclosure relate to semiconductor devices and methods of forming semiconductor devices.

### BACKGROUND

Semiconductor devices are devices that employ semiconductor materials, which are solid materials that exhibit an electrical conductivity lying between that of a conductor and that of an insulator. Semiconductor devices include, for example, diodes (e.g., light emitting diodes (LEDs)), photovoltaic devices, sensors, solid state lasers, and integrated circuits (e.g., memory modules and microprocessors).

Photovoltaic devices are semiconductor devices that convert photons (e.g., light) into electricity. For example, solar panels include photovoltaic devices that convert sunlight (i.e., photons originating from the sun) into electricity. Due to the ever-increasing demand for renewable energy sources, the market for photovoltaic devices has experienced an average annual growth rate of about twenty five percent (25%) over the previous decade.

Extensive research and development has resulted in photovoltaic materials and devices that are cheaper and more efficient. The cost of power produced by photovoltaic devices has decreased significantly over the past several decades, but must be further reduced to become competitive with alternative power sources, such as coal.

A majority of photovoltaic devices that are commercially available at the present time comprise photodiodes formed in silicon substrates. The performance of such silicon-based photovoltaic devices, is however, inherently limited by physical and chemical properties of silicon. New photovoltaic devices have been created that are based on light-absorbing materials (which may be either organic or inorganic) other than silicon. The number of non-silicon-based photovoltaic devices has steadily increased over the previous two (2) decades and currently accounts for over ten percent (10%) of the solar energy market. Non-silicon photovoltaic devices are expected to eventually replace a large portion of the market for silicon-based photovoltaic devices and to expand the solar energy market itself due to their material properties and efficient power generating ability. In order for solar power to be economically competitive with alternative fossil fuel power sources at their current prices, photovoltaic devices based on photoactive materials other than silicon must be improved and further developed.

Materials other than silicon that can be employed in photovoltaic devices include, for example, germanium (Ge), chalcopyrites (e.g., CuInS₂, CuGaS₂, and CuInSe₂), chalcogenides [Cu(InₓGa₁₋ₓ)(SeₓS₁₋ₓ)₂], cadmium telluride (CdTe), gallium arsenide (GaAs), organic polymers (e.g., polyphenylene vinylene, copper phthalocyanine, fullerenes), and light absorbing dyes (e.g., ruthenium-centered metalorganic dyes). Photovoltaic devices based on such materials have demonstrated greater photon conversion efficiencies than those exhibited by silicon-based devices. Furthermore, some non-silicon photovoltaic devices are capable of capturing a broader range of electromagnetic radiation than silicon-based devices, and as such, may be more efficient in producing electrical power from solar energy than are silicon-based devices.

Non-silicon photovoltaic devices may comprise thin films of photoactive materials, which may comprise polycrystalline materials or nanoparticles. The thin films of photoactive materials may be formed on flexible substrates such as polyethylene terephthalate (such as that sold under the trade name Mylar), which allows for a broad range of new configurations, designs, and applications for photovoltaic devices that were previously unavailable to silicon-based devices. Furthermore, thin film designs may use less than one percent (1%) of the raw materials used in conventional silicon-based devices, and therefore, may cost much less than silicon-based devices in terms of basic raw materials.

Manufacturing processes for thin films of photoactive materials include electroplating techniques, vapor deposition, flash evaporation, and evaporation from binary compounds, spray pyrolysis, and radiofrequency or ion beam sputtering of polycrystalline materials. Unfortunately, a majority of the costs associated in producing thin film photoactive devices are incurred in the thin film manufacturing techniques. In addition to being costly, existing thin film manufacturing processes tend to introduce a high number of defects into the films, which can result in an entire batch of material to be rendered inoperable. The next generation of photoactive devices would significantly impact the solar energy market if more efficient thin film manufacturing techniques and improved materials could be developed to overcome limitations of conventional processes and materials.

### BRIEF SUMMARY

In some embodiments, the present disclosure includes methods of forming a photoactive device. Pores of a solid porous ceramic material may be infiltrated with a supercritical fluid carrying at least one single source precursor therein. At least one single source precursor then may be decomposed within the pores of the solid porous ceramic material, and a plurality of particles may be formed within the pores of the solid porous ceramic material from one or more products of the decomposition of at least one single source precursor.

In additional embodiments, the present disclosure includes methods in which at least one single source precursor is decomposed within pores of a solid porous material, a plurality of particles are formed within the pores from one or more products of the decomposition of at least one single source precursor, and the plurality of particles are retained within the pores.

Additional embodiments of the disclosure include photoactive devices comprising a solid porous ceramic material exhibiting an electrical resistivity of less than 10 ohm-cm and a plurality of particles within pores of the solid porous ceramic material, wherein each particle comprising a photoactive semiconductor material.

### BRIEF DESCRIPTION OF THE SEVERAL VIEWS OF THE DRAWINGS

While the specification concludes with claims particularly pointing out and distinctly claiming what are regarded as embodiments of the invention, advantages of embodiments of the disclosure may be more readily ascertained from the following description of certain example embodiments of the disclosure when read in conjunction with the accompanying drawings in which:

FIG. 1 is a simplified perspective view of an embodiment of a photoactive device of the present disclosure that may be formed as described herein;

FIG. 2 is a simplified cross-sectional view of the photoactive device shown in FIG. 1 illustrating different layers thereof;

FIG. 3 is a simplified, enlarged and schematically illustrated view of a portion of the photoactive device shown in FIGS. 1 and 2 that includes nanoparticles of semiconductor material within pores of a conductive material;

FIG. 4 is a simplified cross-sectional view similar to that of FIG. 2 but illustrating another embodiment of a photoactive device of the present disclosure that includes multiple layers including nanoparticles of semiconductor material within pores of a conductive material;

FIG. 5 is a simplified view of another embodiment of a photoactive device of the present disclosure that includes discrete active regions, each of which includes nanoparticles of semiconductor material within pores of a conductive material;

FIG. 6 is a simplified cross-sectional view of the photoactive device shown in FIG. 5 taken along section line 6-6 therein illustrating different layers thereof; and

FIG. 7 is a simplified partial cross-sectional view of a portion of an embodiment of a system of the present disclosure that may be used to subject single source precursors to carbon dioxide to form nanoparticles of semiconductor material within pores of a conductive material in accordance with embodiments of methods of the present disclosure.

### DETAILED DESCRIPTION

The illustrations presented herein are not meant to be actual views of any particular apparatus or system, but are merely idealized representations that are employed to describe various embodiments of the present disclosure. It is noted that elements that are common between figures may retain the same numerical designation.

As used herein, the term “single source precursor” means and includes any molecule or complex that comprises all of the necessary atomic elements, in the appropriate stoichiometric ratios, necessary to form a multinary chalcopyrite material. Single source precursors may comprise so-called organometallic substances. As non-limiting examples, single source precursors include molecules or complexes having the empirical formula [{L}ₙM′(ER)ₓ(X)_{y}(R)_{z}M″], wherein x is 1-4, x+y+z=4, L is a Lewis base that is coordinated to M′ by a dative bond, n is greater than or equal to 1, M′ is a Group I-B atom, M″ is a Group III-A atom, E is a Group VI-A atom, X is a group VII-A atom, and each R is individually selected from the group consisting of alkyl, aryl, vinyl, fluoroalkyl, perfluoro alkyl, fluoroaryl, perfluoro aryl, silane, and carbamato groups. As one particular non-limiting example, ((i-C₄H₉)₃P)₂Cu(C₂H₅S)₂In(C₂H₅S)₂ is a single source precursor. In any single source precursor, fluorine atoms optionally may be substituted for any number of hydrogen atoms in the single source precursor.

As used herein the term “multinary chalcopyrite material” means and includes any material having a composition generally represented by the formula I-III-VI₂, where roman numeral I refers to elements in Group I-B of the periodic table, roman numeral III refers to elements in Group III-A of the periodic table, and roman numeral VI refers to elements in Group VI-A of the periodic table. By multinary, it is meant that the chalcopyrite material contains three or more different types of atoms from three elemental Groups of the periodic table. For example, approximately twenty five percent (25%) of the atoms in a multinary chalcopyrite material are from Group I-B, approximately twenty five percent (25%) of the atoms are from Group III-A, and approximately fifty percent (50%) of the atoms are from Group VI-A. CuInS₂, CuInSe₂, Cu(In,Ga)Se₂, CuGaSe₂, and AgInS₂ are examples of multinary chalcopyrite materials. It should be noted that multinary chalcopyrites may include materials having multiple and/or different atoms from each of three Groups of the periodic table. Multinary charlcopyrite materials include ternary chalcopyrite materials, quaternary chalcopyrite materials, etc. For example, CuInSSe is a quaternary chalcopyrite because it has Cu (Group I-B), In (Group III-A), and S and Se (both from Group VI-A). In addition, molecules of the form (Cu:Ag)(In:Ga)(S:Se), having various ratios of the respectively grouped atoms are all multinary chalcopyrites (Cu and Ag both are in Group I-B, In and Ga both are in Group III-A, S and Se both are in Group VI-A).

As used herein, the term “micropore” means and includes any void in a material having an average cross-sectional dimension of less than 20 angstroms (2 nanometers). For example, micropores include generally spherical pores having average diameter diameters of less than about 20 angstroms, as well as elongated channels having average cross-sectional dimensions of less than about 20 angstroms.

As used herein, the term “mesopore” means and includes any void in a material having an average cross-sectional dimension of greater than about 20 angstroms (2 nanometers) and less than about 500 angstroms (50 nanometers). For example, mesopores include generally spherical pores having average diameters between about 20 angstroms and about 500 angstroms, as well as elongated channels having average cross-sectional dimensions between about 20 angstroms and about 500 angstroms.

As used herein, the term “macropore” means and includes any void in a material having an average cross-sectional dimension of greater than about 500 angstroms (50 nanometers). For example, macropores include generally spherical pores having average diameters greater than about 500 angstroms, as well as elongated channels having average cross-sectional dimensions greater than about 500 angstroms.

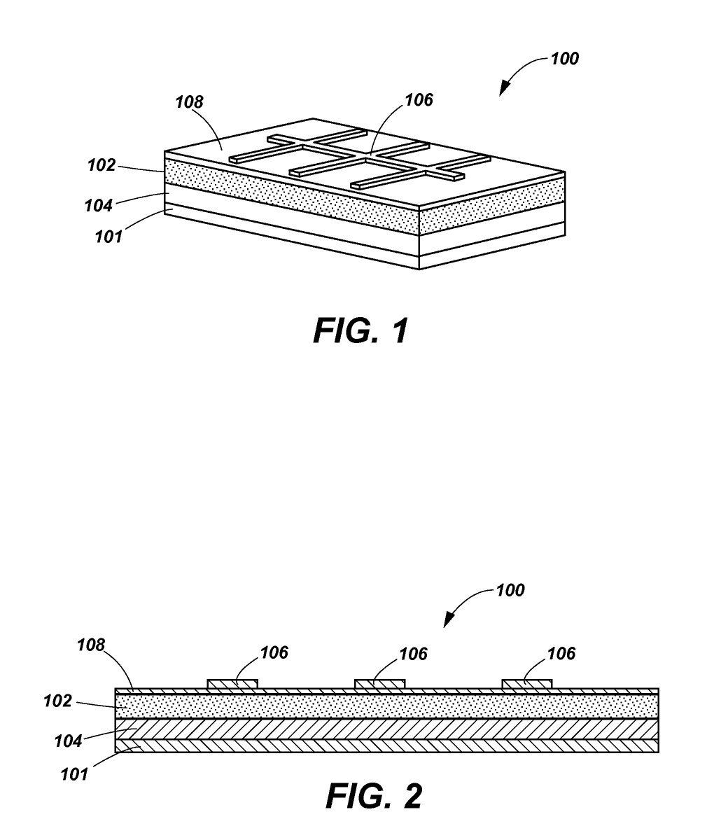

An embodiment of a photoactive device 100 of the present disclosure is shown in FIGS. 1 and 2. The photoactive device 100 includes an integral composite photon absorber material 102. The composite photon absorber material 102 may be configured as a substantially planar layer, as shown in FIGS. 1 and 2. In such embodiments, the layer of photon absorber material 102 may have an average total thickness of between about ten nanometers (10 nm) and about one hundred microns (100 μm).

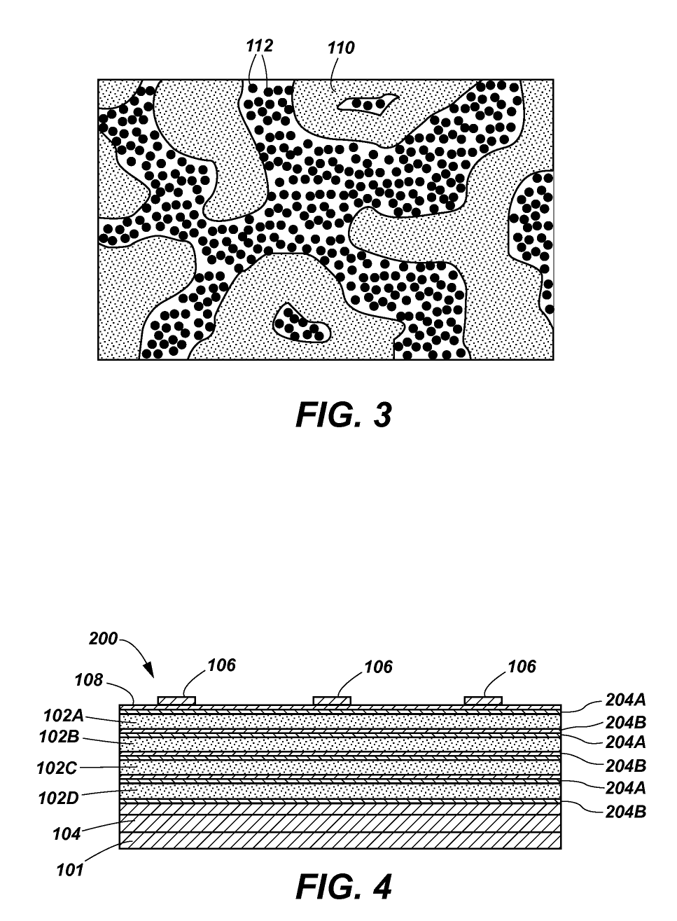

As discussed in further detail below with reference to FIG. 3, the composite photon absorber material 102 includes a solid porous and electrically conductive ceramic material, and a plurality of particles comprising a photoactive semiconductor material disposed within pores of the solid porous ceramic material.

With continued reference to FIGS. 1 and 2, the photoactive device 100 may further include a first electrode 104 and a second electrode 106. The photon absorber material 102 may be disposed between the first electrode 104 and the second electrode 106. In other words, the first electrode 104 may be separated from the second electrode 106 by the photon absorber material 102. For example, the first electrode 104 may be electrically coupled (either directly or indirectly) to a first side of the photon absorber material 102, and the second electrode 106 may be coupled (either directly or indirectly) to an opposing side of the photon absorber material 102. Optionally, an antireflective coating (ARC) 108 may be provided between the photon absorber material 102 and the second electrode 106, as shown in FIGS. 1 and 2. Furthermore, the photoactive device 100 may comprise at least a portion of a substrate 101, on which one or more of the various layers of the photoactive device 100 may be formed.

In some embodiments, the first electrode 104 may comprise an at least substantially continuous sheet or layer of conductive material (e.g., molybdenum, copper, nickel, aluminum, silver, doped semiconductor materials, etc.), and the second electrode 106 may comprise horizontally extending (with respect to a major plane of the photoactive device 100), interconnected conductive lines or traces, which may be formed by patterning (e.g., masking and etching) an at least substantially continuous sheet or layer of conductive material like that of the first electrode 104.

The optional antireflective coating 108 may comprise any material known in the art for antireflective coatings, such as, for example, silicon nitride (Si₃N₄) or silica (SiO₂). Furthermore, the substrate 101 may comprise, for example, a full or partial wafer of semiconductor material (e.g., silicon, germanium, gallium arsenide, indium phosphide, and other III-V type semiconductor materials), a full or partial silicon-on-insulator (SOI) type substrate, a full or partial silicon-on-sapphire (SOS) type substrate, a full or partial wafer of dielectric material, etc.

FIG. 3 is a simplified, enlarged and schematically illustrated cross-sectional view of the composite photon absorber material 102 of the photoactive device 100 of FIG. 1. As shown in FIG. 3, the composite photon absorber material 102 includes a solid porous ceramic material 110, and a plurality of particles 112 disposed within pores of the solid porous ceramic material 110. The particles 112 are schematically illustrated as black circular dots in FIG. 3.

The solid porous ceramic material 110 may exhibit an electrical resistivity of less than ten (10) ohm-cm. In some embodiments, the solid porous ceramic material 110 may exhibit an electrical resistivity of less than one (1) ohm-cm. In some embodiments, the solid porous ceramic material 110 may comprise one or more of titanium oxide, magnesium oxide, zinc oxide, indium sulfide, indium selenide, molybdenum oxide, tin oxide, zinc sulfide, cadmium sulfide, zinc selenide, and cadmium selenide. As a non-limiting example, the solid porous ceramic material 110 may comprise anatase phase titanium dioxide. In some embodiments, the solid porous ceramic material 110 may comprise a semiconductor material, which has been doped to render the material conductive. For example, the material of the solid porous ceramic material 110 may be doped with one or more elements such as tantalum or niobium to increase the electrical conductivity of the solid porous ceramic material 110.

The pores within the solid porous ceramic material 110 may comprise a three-dimensionally continuous open network of pores. In other words, continuous pathways may extend through the porous of the solid porous ceramic material 110 from the side thereof adjacent the first electrode 104 to the side thereof adjacent the second electrode 106. In some embodiments, the pores within the solid porous ceramic material 110 may comprise micropores, such that the solid porous ceramic material 110 comprises a microporous material. In other embodiments, the pores within the solid porous ceramic material 110 may comprise mesopores, such that the solid porous ceramic material 110 comprises a mesoporous material. In yet further embodiments, the pores within the solid porous ceramic material 110 may comprise macropores, such that the solid porous ceramic material 110 comprises a macroporous material.

The solid ceramic phase of the solid porous ceramic material 110 also may be continuous in three dimensions, such that continuous pathways extend through the solid ceramic phase of the solid porous ceramic material 110 from the side thereof adjacent the first electrode 104 to the side thereof adjacent the second electrode 106.

By way of example and not limitation, the solid porous ceramic material 110 may comprise a layer of the solid porous ceramic material 110 having an average total layer thickness of between about ten nanometers (10 nm) and about five hundred microns (500 μm), between about one hundred nanometers (100 nm) and about one hundred microns (100 μm), or even between about one micron (1 μm) and about fifty microns (50 μm).

In some embodiments, the overall composition of the composite photon absorber material 102 may be generally homogenous across the layer of the composite photon absorber material 102. In other embodiments, however, the composition may vary across the thickness of the composite photon absorber material 102. For example, one side of the composite photon absorber material 102 may be at least substantially comprised of the solid porous ceramic material 110, an opposing side of the composite photon absorber material 102 may be at least substantially comprised of the material of the particles 112, and the relative concentrations of each of the solid porous ceramic material 110 and the particles 112 may vary across the thickness of the composite photon absorber material 102 in a stepwise or a continuous manner.

As discussed in further detail below, the solid porous ceramic material 110 may be formed to comprise a microstructure as described herein by forming the solid porous ceramic material 110 using a sol-gel process, such as a traditional sol-gel process used to form a xerogel, or an aerogel process.

With continued reference to FIG. 3, each of the particles 112 may comprise a photoactive semiconductor material. In some embodiments, the particles 112 may comprise a chalcopyrite material (e.g., a multinary chalcopyrite material, such as CuInS₂, CuInSe₂, Cu(In,Ga)(S,Se)₂, CuGaSe₂, or AgInS₂). Further, the particles 112 may comprise nanoparticles in some embodiments of the invention. In other words, the particles 112 may have an average particle size of about one hundred nanometers (100 nm) or less. In some embodiments, the particles 112 may have an average particle size of about seventy five nanometers (75 nm) or less, about fifty nanometers (50 nm) or less, or even between about two nanometers (2 nm) and about twenty nanometers (20 nm) (e.g., about fifteen nanometers (15 nm)).

The ceramic material 110 and the particles 112 may comprise different materials that exhibit different energy band structures. The particles 112 may operate as the photon absorbing material of the composite photon absorber material 102 in which photons are absorbed resulting in electron-hole pairs, and the ceramic material 110 may serve as a collector which collects the electrons of the electron-hole pairs generated within the particles 112 and channels the electrons to the first electrode 104 (FIGS. 1 and 2). By filling the pores of the ceramic material 110 with the particles 112, the degree of contact between the particles 112 and the ceramic material 110 may be increased, which may reduce the probability that electron-hole pairs generated within the particles 112 will recombine and annihilate with one another prior to drifting apart due to an electric field at the interfaces between the particles 112 and the ceramic material 110, and being separated and collected at the first electrode 104 and the second electrode 106, respectively, thereby resulting in improved efficiency.

The photoactive device 100 of FIGS. 1 and 2 includes a single body of the composite photon absorber material 102. In additional embodiments of the disclosure, photoactive devices may include two or more bodies of such a composite photon absorber material 102. FIG. 4 illustrates an embodiment of a photoactive device 200 of the present disclosure. The photoactive device 200, like the photoactive device 100, optionally may comprise a first electrode 104, a second electrode 106, an antireflective coating (ARC) 108, and a substrate 101, as previously described with reference to the photoactive device 100 shown in FIGS. 1 and 2. The photoactive device 200, however, may include a plurality of discrete bodies of composite photon absorber material 102 as previously described with reference to FIG. 3. By way of example, the photoactive device 200 may include a first layer of composite photon absorber material 102A, a second layer of composite photon absorber material 102B, a third layer of composite photon absorber material 102C, and a fourth layer of composite photon absorber material 102D, each of which may include a plurality of particles 112 disposed within pores of a solid porous ceramic material 112 as previously described with reference to FIG. 3.

As shown in FIG. 4, a p-type hole conducting layer 204A may be disposed on one side of each of the layers of composite photon absorber material 102A-102D, and an n-type electron conducting layer 204B may be disposed on an opposing side of each of the layers of composite photon absorber material 102A-102D. Although not visible in the cross-sectional view of FIG. 4, each of the hole conducting layers 204A may be in electrical contact with either the first electrode 104 or the second electrode 106, and each of the electron conducting layers 204B may be in electrical contact with the other of the first electrode 104 and the second electrode 106. By way of example and not limitation, the hole conducting layers 204A may comprise an extrinsic or intrinsic p-type I-III-VI₂ semiconductor material, and the electron conducting layers 204B may comprise an extrinsic or intrinsic n-type I-III-VI₂ semiconductor material.

In some embodiments, each of the layers of composite photon absorber material 102A-102D may be formed using particles 112 having at least substantially similar chemical compositions. As a nonlimiting example, each of the layers of composite photon absorber material 102A-102D may be formed using nanoparticles comprising CuInₛ₂. In other embodiments, the layers of composite photon absorber material 102A-102D each may be formed using particles 112 having differing chemical compositions.

Furthermore, in some embodiments, each of the layers of composite photon absorber material 102A-102D may be formed using particles 112 having at least substantially similar average particle sizes. In other embodiments, the layers of composite photon absorber material 102A-102D each may be formed using particles 112 having differing average particle sizes. As a nonlimiting example, the first layer of composite photon absorber material 102A may be formed using nanoparticles having an average particle size of about three nanometers (3 nm), the second layer of composite photon absorber material 102B may be formed using nanoparticles having an average particle size of about five nanometers (5 nm), the third layer of composite photon absorber material 102C may be formed using nanoparticles having an average particle size of about seven nanometers (7 nm), and the fourth layer of composite photon absorber material 102D may be formed using nanoparticles having an average particle size of about nine nanometers (9 nm). In this configuration, each of the layers of composite photon absorber material 102A-102D may be responsive to differing ranges of wavelengths of electromagnetic radiation.

Depending on the composition and configuration of the different material layers of the photoactive device 200 shown in FIG. 4, the photoactive device 200 may comprise a diode (e.g., a light emitting diode (LED)), a photovoltaic device, a radiation sensor, a solid state laser device, or another photoactive device.

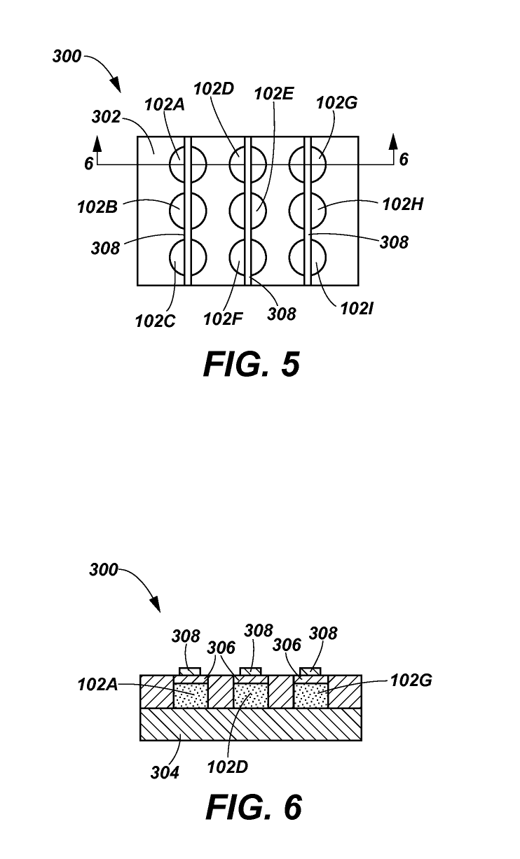

Yet another embodiment of a photoactive device 300 of the present disclosure is shown in FIGS. 5 and 6. Referring to FIG. 5, the device 300 may comprise a plurality of spatially separated and discrete volumes of composite photon absorber material 102 as previously described with reference to FIG. 3. The photoactive device 300 shown in FIGS. 5 and 6, which has been simplified for purposes of illustration, includes nine (9) volumes of composite photon absorber material 102A, 102B, 102C, . . . 102I. In actuality, however, the photoactive device 300 may comprise any number (e.g., tens, hundreds, thousands, millions, etc.) of discrete volumes of composite photon absorber material 102. Each volume of composite photon absorber material 102A-102I may be surrounded by a dielectric material 302 that is electrically insulating. As a non-limiting example, the layer of dielectric material 302 may comprise SiO₂.

Referring to FIG. 6, the device 300 may comprise a conductive layer 304 (which may or may not be formed on another substrate). The conductive layer 304 may comprise an at least substantially continuous layer of conductive material like those previously described in relation to the first electrode 104 shown in FIGS. 1 and 2. Each volume of composite photon absorber material 102A-102I comprises a plurality of particles 112 disposed within pores of a solid porous ceramic material 112 as previously described with reference to FIG. 3. Electrical contact may be provided between each volume of composite photon absorber material 102A-102I and the conductive layer 304.

A conductive plug 306 may be provided over each of the volumes of composite photon absorber material 102A-102I, and each conductive plug 306 may be in electrical contact with one or more conductive lines or traces 308. The conductive lines or traces 308 may extend to other circuitry and electrical components (not shown) of the device 300. In this configuration, each volume of composite photon absorber material 102A-102I may be disposed between, and electrically coupled to each of, the conductive layer 304, which may function as a first electrode, and a conductive line or trace 308, which may serve as a second electrode.

In some embodiments, one or more of the volumes of composite photon absorber material 102A-102I may differ in one or more chemical and/or physical aspects from other volumes of composite photon absorber material 102A-102I.

As one non-limiting example, the volumes of composite photon absorber material 102A-102I may include particles 112 (FIG. 3) having differing chemical compositions. By way of example and not limitation, the volumes of composite photon absorber material 102A-102C may comprise nanoparticles having a first chemical composition, the volumes of composite photon absorber material 102D-102F may comprise nanoparticles having a second chemical composition that differs from the first chemical composition, and the volumes of composite photon absorber material 102G-102I may comprise nanoparticles having a third chemical composition that differs from the first and second chemical compositions.

As another non-limiting example, the volumes of composite photon absorber material 102A-102I may be formed using particles 112 having differing average particle sizes. By way of example and not limitation, the volumes of composite photon absorber material 102A-102C comprise nanoparticles having an average particle size of about three nanometers (3 nm), the volumes of composite photon absorber material 102D-102F may comprise nanoparticles having an average particle size of about five nanometers (5nm), and the volumes of composite photon absorber material 102G-102I may comprise nanoparticles having an average particle size of about seven nanometers (7 nm). In this configuration, different volumes of composite photon absorber material 102A-102I may be responsive to differing ranges of wavelengths of electromagnetic radiation.

Depending on the composition and configuration of the different material layers of the photoactive device 300 shown in FIGS. 5 and 6, the photoactive device 300 may comprise a diode (e.g., a light emitting diode (LED)), a photovoltaic device, a radiation sensor, a solid state laser device, or any other semiconductor device.

Additional embodiments of the disclosure include methods of forming photoactive devices, such as those described hereinabove.

Broadly, the methods include forming or otherwise providing a plurality of particles 112 within the pores of a solid porous ceramic material 110. The solid porous ceramic material 110 may be selected to comprise a ceramic material 110 as previously described with reference to FIGS. 1 through 3, and the plurality of particles 112 also may be selected to comprise a plurality of particles 112 as previously described with reference to FIGS. 1 through 3.

In some embodiments, pores of the solid porous ceramic material 110 may be infiltrated with a supercritical fluid carrying at least one single source precursor (SSP) therein, and then at least one single source precursor may be decomposed within the pores of the solid porous ceramic material 110 to form the plurality of particles 112 within the pores from one or more products of the decomposition of at least one single source precursor.

As previously described herein, the porous ceramic material 110 may be selected to comprise on oxide, such as one or more of titanium oxide, magnesium oxide, and zinc oxide in some embodiments. As a non-limiting example, the porous ceramic material 110 may be selected to comprise anatase phase titanium dioxide. Further, the porous ceramic material 110 may be selected to comprise a microporous, mesoporous, or macroporous ceramic material 110.

In some embodiments, the methods of the disclosure include forming the solid porous ceramic material 110. The solid porous ceramic material 110 may be formed using, for example, a sol-gel process for forming an aerogel or a xerogel, which is capable of forming a porous ceramic material 110 having a composition and microstructure as previously described herein with reference to FIGS. 1 through 3.

In a sol-gel process, a solution is formed that includes metal alkoxides or metal chlorides, which undergo various forms of hydrolysis and polycondensation reactions to form the porous ceramic material 110. The solution is transformed into a gel, which may include a liquid phase and a solid phase. The transformation of the solution into the gel may include one or more reactions, such as a hydrolysis reaction and/or a polymerization reaction. After forming the gel, the gel is dried to remove the liquid phase, leaving the porous solid phase behind. If the liquid phase is dried by evaporation of the liquid phase to the gaseous phase, the resulting porous solid structure may be referred to as a “xerogel.” The porous solid phase of the xerogel then may be fired (i.e., sintered) to remove any remaining liquid phase and to strengthen and partially densify the porous solid phase.

An aerogel process is generally similar to a sol-gel process, and includes the formation of a solution that includes precursor compounds or chemical species including the elements eventually used to form the porous ceramic material 110. The solution is transformed into a gel, which may include a liquid phase and a solid phase. The transformation of the solution into the gel may include one or more reactions, such as a hydrolysis reaction and/or a polymerization reaction. In an aerogel process, however, the liquid phase is removed from the gel by supercritical drying. In the supercritical drying process, the liquid phase in the gel may be transformed into a supercritical fluid, which then may be gasified and removed from the solid phase. In other words, the liquid phase does not transform directly into the gaseous phase, but rather from the liquid phase into a supercritical phase, which is removed from the solid phase. The porous solid structure that results from such a process is often referred to in the art as an “aerogel.” The porous aerogel then may be fired (i.e., sintered) to strengthen and partially densify the porous solid phase.

Sol-gel processes for forming solid porous ceramic materials having different compositions and microstructures, such as those described herein, are known in the art and may be employed in embodiments of the disclosure.

By way of example and not limitation, a layer of the solid porous ceramic material 110 may be formed over the first electrode 104 of FIGS. 1 and 2 using a spin-coating process or a dip-coating process to deposit a layer of solution over the first electrode 104 (and, optionally, the substrate 101 of FIGS. 1 and 2). The layer of solution then may be transformed into a gel, which then may be dried to form a xerogel or an aerogel. The xerogel or aerogel then optionally may be heated (e.g., in a furnace) to form the solid porous ceramic material 110.

After providing the solid porous ceramic material 110, the particles 112 may be provided within the pores of the solid porous ceramic material 110.

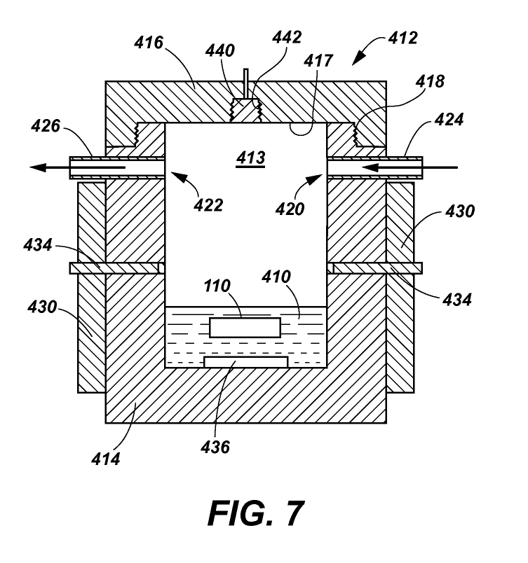

An example of a method and system that may be used to provide the particles 112 within the pores of the solid porous ceramic material 110 are disclosed below with reference to FIG. 7.

Referring to FIG. 7, a single source precursor 410 may be provided in a pressure vessel 412 or another form of a container. The pressure vessel 412 may comprise a pressure vessel 412 as disclosed in U.S. Patent Application Publication No. 2009/0233398 A1, filed Mar. 13, 2008 and entitled “Methods for Forming Particles from Single Source Precursors, Methods of Forming Semiconductor Devices, and Devices Formed Using Such Methods,” which is incorporated herein in its entirety by this reference. Additionally, the SSP 410 may comprise and SSP as disclosed therein, or in U.S. patent application Ser. No. 12/646,474, filed Dec. 23, 2009 and entitled “Methods of Forming Single Source Precursors, Methods of Forming Polymeric Single Source Precursors, and Single Source Precursors and Intermediate Products Formed by Such Methods,” which is also incorporated herein in its entirety by this reference.

The pressure vessel 412 may comprise any enclosure or container having an interior region or cavity 413 for holding pressurized fluids (e.g., liquids, gasses, and supercritical fluids). As a non-limiting example, the pressure vessel 412 may comprise a main body 414 and a cap 416, which may be secured together by complementary threads 418, as shown in FIG. 7. Although not shown, grease and/or one or more seals (e.g., O-rings) may be used to provide a fluid-tight seal between the main body 414 and the cap 416.

The pressure vessel 412 may include an inlet 420 for conveying pressurized fluids into the cavity 413, and an outlet 422 for conveying fluids out from the cavity 413. A first conduit 424 may extend through the body 414 of the pressure vessel 412 to the inlet 420 of the cavity 413, and a second conduit 426 may extend from the outlet 422 of the cavity 413 through the body 414 of the pressure vessel. A carbon dioxide (CO₂) source (not shown) may be used to supply pressurized carbon dioxide to the cavity 413 through the first conduit 424 and the inlet 420. If the carbon dioxide source does not provide pressurized carbon dioxide, a separate pump (not shown) optionally may be used to pressurize the carbon dioxide. The second conduit 426 may lead to a check valve (not shown), which may be used to maintain a desired pressure within the cavity 413. In this configuration, carbon dioxide may be supplied to the cavity 413 and, optionally, may be caused to flow through the cavity 413 from the inlet 420 to the outlet 422.

One or more heating elements 430 (e.g., resistive heating elements) may be used to heat the pressure vessel 412 and the contents thereof. Furthermore, one or more temperature sensors 434 may be used to measure a temperature within the cavity 413. A temperature controller (not shown) (e.g., a computer device or a programmable logic controller) may be used to control a temperature of the contents within the pressure vessel 412 by measuring the temperature of the contents using the one or more temperature sensors 434, and, in response to the measured temperature, selectively applying heat to the contents using the one or more heating elements 430. Although not shown, a cooling system also may be employed to provide further control over the temperature of the contents within the pressure vessel 412.

Optionally, one or more ultrasonic transducers 440 may be positioned and configured to impart ultrasonic vibrations to contents within the cavity 413 of the pressure vessel 412. As a non-limiting example, a recess 442 may be formed in (e.g., machined into) the inner surface 417 of the cap 416, and an ultrasonic transducer 440 may be positioned within (e.g., threaded into) the recess 442. In other embodiments, one or more ultrasonic transducers 440 may be positioned within recesses in the side walls and/or the bottom wall of the body 414 of the pressure vessel 412.

With continued reference to FIG. 7, a body of porous solid ceramic material 110 also may be provided within the pressure vessel 412. In some embodiments, the body of porous solid ceramic material 110 may be partially or totally immersed within the SSP 410. In other embodiments, the body of porous solid ceramic material 110 may be positioned within the pressure vessel 412 over the SSP 410.

Carbon dioxide then may be introduced into cavity 413 of the pressure vessel 412 through the first conduit 424 and the inlet 420. Upon mixing of the carbon dioxide with the SSP 410, carbon dioxide may carry the SSP 410. The carbon dioxide carrying the SSP 410 may infiltrate the pores of the body of porous solid ceramic material 110.

The SSP 410 may decompose within the pores of the body of porous solid ceramic material 110 to form and retain particles 112 of multinary chalcopyrite material within pores of the ceramic material 110. Other products of the decomposition of the SSP 410 may be dissolved in and carried away by the carbon dioxide through the outlet 422 and the second conduit 426. Such products of the decomposition of the SSP 410 may be referred to as “leaving groups.”

By way of example and not limitation, a SSP 410 may be provided within the pressure vessel 412, and the SSP 410 may be heated to a temperature greater than about eighteen degrees Celsius (18° C.). In some embodiments, the temperature of the SSP 410 may be heated to a temperature greater than about thirty-one point one degrees Celsius (31.1° C.), which is the critical temperature of carbon dioxide. The SSP 410 may be susceptible to thermal decomposition at temperatures above a certain threshold thermal decomposition temperature, which is dependent on the particular composition of the SSP 410. Therefore, it may be desirable to maintain the temperature of the SSP 410 below the thermal decomposition temperature of the particular SSP 410 being used. As a nonlimiting example, it may be desirable to maintain the temperature of the SSP 410 below about one hundred and fifty degrees Celsius (150° C.).

After bringing the temperature of the SSP 410 to temperature, carbon dioxide may be caused to flow into and through the cavity 413 from the inlet 420 to the outlet 422. The carbon dioxide may, in some embodiments, be in the supercritical state. For example, the carbon dioxide may be at a temperature at or above about thirty-one point one degrees Celsius (31.1° C.) and at a pressure at or above about 7.38 megapascals (MPa). In other embodiments, however, the carbon dioxide may be in the liquid state, and not in the supercritical state. For example, in some embodiments, the temperature of the carbon dioxide may be as low as about eighteen degrees Celsius (18° C.), and the pressure of the carbon dioxide may be as low as about five point five megapascals (5.5 MPa). While it may be desirable to maintain the temperature of the carbon dioxide below the threshold thermal decomposition temperature of the SSP 410, the pressure of the carbon dioxide may be as high as fifty megapascals (50 MPa) or more.

As the carbon dioxide is caused to flow into and through the cavity 413, a mixing mechanism or device 436 may, optionally, be used to enhance mixing of the carbon dioxide with the SSP 410. For example, the mixing mechanism or device may comprise a magnetic stir rod, which may be rotated within the SSP 410 as the carbon dioxide flows through the cavity 413. In other embodiments, however, a mixing mechanism or device 436 may not be used. After flowing the carbon dioxide through the cavity 413 for a period of time, the carbon dioxide and the SSP 410 may infiltrate the pores of the ceramic material 110 and decompose to form particles 112 of multinary chalcopyrite material within the pores of the ceramic material 110. The exact length of time required to form the particles 112 of multinary chalcopyrite material may depend upon one or more of the composition of the SSP 410, the temperature and pressure of the SSP 410 and the carbon dioxide, the rate of flow of carbon dioxide through the cavity 413, and the extent of mixing provided between the SSP 410 and the carbon dioxide.

As the SSP 410 is subjected to the carbon dioxide within the cavity 413, ultrasonic vibrations may be imparted to the mixture using the one or more ultrasonic transducers 440. By imparting ultrasonic vibrations to the mixture, the temperature required to cause decomposition of the SSP 410 may be reduced and/or the decomposition reaction may be driven further to completion.

As one nonlimiting example, the cavity 413 may be generally cylindrical. The cavity 413 may be heated to greater than about one hundred degrees Celsius (100° C.) to drive any water out from the cavity 413. Some SSPs, such as ((i-C₄H₉)₃P)₂Cu(C₂H₅S)₂In(C₂H₅S)₂, are sensitive to moisture and should be kept over a desiccant prior to use. The temperature of the cavity 413 then may be reduced to about seventy-five degrees Celsius (75° C.), and about four hundred microliters (400 μl) of ((i-C₄H₉)₃P)₂Cu(C₂H₅S)₂In(C₂H₅S)₂ may be provided within the cavity 413. Carbon dioxide then may be pumped into the cavity 413 and pressurized to about twenty point seven megapascals (20.7 MPa). A magnetic stir bar then may be rotated within the cavity 413 for about five minutes (5.0 min.). Carbon dioxide then may be caused to flow through the cavity 413 while maintaining the temperature in the cavity 413 between about sixty-six degrees Celsius (66° C.) and about one hundred and fifty degrees Celsius (150° C.) and the pressure in the cavity above about twenty megapascals (20.0 MPa). More particularly, the temperature in the cavity 413 may be maintained at about seventy five degrees Celsius (75° C.) and the pressure in the cavity 413 may be maintained at about twenty point seven megapascals (20.7 MPa). Upon completion of this process, at least substantially all of the ((i-C₄H₉)₃P)₂Cu(C₂H₅S)₂In(C₂H₅S)₂ may have decomposed to form nanoparticles of CuInS₂, which may have an average particle size of about three nanometers (3 nm) or less. This particular method is set forth as a nonlimiting example, and other methods of forming particles from SSPs by subjecting the SSPs to carbon dioxide are within the scope of the present disclosure.

Optionally, certain additives may be mixed with the SSP 410 prior to introducing the carbon dioxide into the cavity 413 to facilitate the decomposition of the SSP 410. By way of example and not limitation, alkane thiols or polythiols may be mixed with the SSP 410 to facilitate the decomposition of the SSP 410 upon subjecting the SSP 410 to the carbon dioxide, as previously discussed. Such additives are believed to form a complex with the SSP 410 that effectively reduces the activation energy for the decomposition process. As a nonlimiting example, a volume of alkane dithiol equal to between about one half percent (0.5%) and about five percent (5.0%) of the volume of the SSP 410 may be mixed with the SSP 410 prior to introducing the carbon dioxide into the cavity 410.

Optionally, subsequent processes may be used to promote adhesion of the particles 112 to one another and to the internal surfaces of the ceramic material 110, which may further assist in retention of the particles 112 within the pores of the ceramic material 110. For example, the particles 112 and the ceramic material 110 may be subjected to an annealing process to promote further bonding of the particles 110 to one another and to the ceramic material 110.

Additional non-limiting example embodiments of the invention are described below.

### Embodiment 1

A method of forming a photoactive device, comprising: infiltrating pores of a solid porous ceramic material with a supercritical fluid carrying at least one single source precursor therein; and decomposing the at least one single source precursor within the pores of the solid porous ceramic material and forming a plurality of particles within the pores of the solid porous ceramic material from one or more products of the decomposition of the at least one single source precursor.

### Embodiment 2

The method of Embodiment 1, further comprising selecting the supercritical fluid to comprise supercritical CO₂.

### Embodiment 3

The method of Embodiment 1 or Embodiment 2, wherein forming a plurality of particles within the pores of the solid porous ceramic material comprises forming a plurality of nanoparticles within the pores of the solid porous ceramic material.

### Embodiment 4

The method of Embodiment 3, wherein forming a plurality of nanoparticles within the pores of the solid porous ceramic material comprises forming a plurality of particles each comprising a chalcopyrite material within the pores of the solid porous ceramic material.

### Embodiment 5

The method of any of Embodiments 1 through 4, further comprising selecting the solid porous ceramic material to comprise a material exhibiting a resistivity less than about 10 ohm-cm.

### Embodiment 6

The method of Embodiment 5, further comprising selecting the solid porous ceramic material to comprise at least one of titanium oxide, magnesium oxide, zinc oxide, indium sulfide, indium selenide, molybdenum oxide, tin oxide, zinc sulfide, cadmium sulfide, zinc selenide, and cadmium selenide.

### Embodiment 7

The method of Embodiment 6, further comprising selecting the solid porous ceramic material to comprise anatase phase titanium dioxide.

### Embodiment 8

The method of Embodiment 7, further comprising selecting the anatase phase titanium dioxide to comprise macroporous anatase phase titanium dioxide.

### Embodiment 9

The method of any one of Embodiments 1 through 5, further comprising selecting the solid porous ceramic material to comprise macroporous ceramic material.

### Embodiment 10

The method of any one of Embodiments 1 through 9, further comprising selecting the solid porous ceramic material to comprise a layer of the solid porous ceramic material having an average total layer thickness of between about 10 nm and about 500 μm.

### Embodiment 11

The method of any one of Embodiments 1 through 10, further comprising forming the solid porous ceramic material.

### Embodiment 12

The method of Embodiment 11, wherein forming the solid porous ceramic material comprises forming the solid porous ceramic material using a sol-gel process.

### Embodiment 13

The method of Embodiment 11, wherein forming the solid porous ceramic material comprises forming the solid porous ceramic material using an aerogel process.

### Embodiment 14

A method, comprising: decomposing at least one single source precursor within pores of a solid porous material; and forming a plurality of particles within the pores from one or more products of the decomposition of the at least one single source precursor; and retaining the plurality of particles within the pores.

### Embodiment 15

The method of Embodiment 14, further comprising selecting the solid porous material to comprise a material exhibiting a resistivity of less than 10 ohm-cm.

### Embodiment 16

The method of Embodiment 14 or Embodiment 15, further comprising selecting the solid porous material to comprise a ceramic material.

### Embodiment 17

The method of any one of Embodiments 14 through 16, further comprising selecting the solid porous material to comprise macroporous anatase titanium dioxide.

### Embodiment 18

The method of any one of Embodiments 14 through 17, wherein forming a plurality of particles within the pores comprises forming a plurality of particles each comprising a photoactive semiconductor material within the pores.

### Embodiment 19

The method of Embodiment 18, wherein forming a plurality of particles each comprising a photoactive semiconductor material within the pores comprises forming a plurality of particles each comprising a chalcopyrite material within the pores.

### Embodiment 20

The method of Embodiment 19, wherein forming a plurality of particles each comprising a chalcopyrite material within the pores comprises forming a plurality of particles each comprising a multinary chalcopyrite material within the pores.

### Embodiment 21

A photoactive device, comprising: a solid porous ceramic material exhibiting an electrical resistivity of less than about 10 ohm-cm and a plurality of particles within pores of the solid porous ceramic material, each particle comprising a photoactive semiconductor material.

### Embodiment 22

The photoactive device of Embodiment 21, wherein the solid porous ceramic material has an electrical resistivity of less than about 1 ohm-cm.

### Embodiment 23

The photoactive device of Embodiment 21 or Embodiment 22, wherein the solid porous ceramic material comprises at least one of titanium oxide, magnesium oxide, zinc oxide, indium sulfide, indium selenide, molybdenum oxide, tin oxide, zinc sulfide, cadmium sulfide, zinc selenide, and cadmium selenide.

### Embodiment 24

The photoactive device of Embodiment 23, wherein the solid porous ceramic material comprises anatase phase titanium dioxide.

### Embodiment 25

The photoactive device of Embodiment 24, wherein the anatase phase titanium dioxide comprises macroporous anatase phase titanium dioxide.

### Embodiment 26

The photoactive device of any one of Embodiments 21 through 23, wherein the solid porous ceramic material comprises macroporous ceramic material.

### Embodiment 27

The photoactive device of any one of Embodiments 21 through 26, wherein the solid porous ceramic material comprises a layer of the solid porous ceramic material having an average total layer thickness of between about 10 nm and about 500 μm.

### Embodiment 28

The photoactive device of any one of Embodiments 21 through 27, wherein the solid porous ceramic material comprises anatase phase ceramic material.

### Embodiment 29

The photoactive device of any one of Embodiments 21 through 28, wherein the photoactive semiconductor material comprises a chalcopyrite material within the pores.

### Embodiment 30

The photoactive device of Embodiment 29, wherein the chalcopyrite material comprises a multinary chalcopyrite material.

### Embodiment 31

The photoactive device of any one of Embodiments 21 through 30, wherein the solid porous ceramic material comprises a solid ceramic phase continuous in three dimensions.

### Embodiment 32

The photoactive device of any one of Embodiment 21 through 31, wherein pores of the solid porous ceramic material comprise an open pore network continuous in three dimensions.

While embodiments of the disclosure may be susceptible to various modifications and alternative forms, specific embodiments have been shown by way of example in the drawings and have been described in detail herein. However, it should be understood that the invention is not intended to be limited to the particular forms disclosed. Rather, the invention includes all modifications, equivalents, and alternatives falling within the scope of the invention as defined by the following appended claims and their legal equivalents.

What is claimed is:

1. A method of forming a photoactive device, comprising:
infiltrating pores of a solid porous ceramic material with a supercritical fluid carrying at least one single source precursor therein; and
decomposing the at least one single source precursor within the pores of the solid porous ceramic material and forming a plurality of particles within the pores of the solid porous ceramic material from one or more products of the decomposition of the at least one single source precursor.

2. The method of claim 1, further comprising selecting the supercritical fluid to comprise supercritical CO₂.

3. The method of claim 1, wherein forming a plurality of particles within the pores of the solid porous ceramic material comprises forming a plurality of nanoparticles within the pores of the solid porous ceramic material.

4. The method of claim 3, wherein forming a plurality of nanoparticles within the pores of the solid porous ceramic material comprises forming a plurality of particles each comprising a chalcopyrite material within the pores of the solid porous ceramic material.

5. The method of claim 1, further comprising selecting the solid porous ceramic material to comprise a material exhibiting an electrical resistivity of less than about 10 ohm-cm.

6. The method of claim 5, further comprising selecting the solid porous ceramic material to comprise at least one of titanium oxide, magnesium oxide, zinc oxide, indium sulfide, indium selenide, molybdenum oxide, tin oxide, zinc sulfide, cadmium sulfide, zinc selenide, and cadmium selenide.

7. The method of claim 6, further comprising selecting the solid porous ceramic material to comprise anatase phase titanium dioxide.

8. The method of claim 7, further comprising selecting the anatase phase titanium dioxide to comprise macroporous anatase phase titanium dioxide.

9. The method of claim 1, further comprising selecting the solid porous ceramic material to comprise macroporous ceramic material.

10. The method of claim 1, further comprising selecting the solid porous ceramic material to comprise a layer of the solid porous ceramic material having an average total layer thickness of between about 10 nm and about 500 μm.

11. The method of claim 1, further comprising forming the solid porous ceramic material.

12. The method of claim 11, wherein forming the solid porous ceramic material comprises forming the solid porous ceramic material using a sol-gel process.

13. The method of claim 11, wherein forming the solid porous ceramic material comprises forming the solid porous ceramic material using an aerogel process.

14. A method, comprising:
decomposing at least one single source precursor within pores of a solid porous material;
forming a plurality of particles within the pores from one or more products of the decomposition of the at least one single source precursor; and
retaining the plurality of particles within the pores.

15. The method of claim 14, further comprising selecting the solid porous material to comprise a material exhibiting an electrical resistivity of less than about 10 ohm-cm.

16. The method of claim 15, further comprising selecting the solid porous material to comprise a ceramic material.

17. The method of claim 16, further comprising selecting the solid porous material to comprise macroporous anatase titanium dioxide.

18. The method of claim 14, wherein forming a plurality of particles within the pores comprises forming a plurality of particles each comprising a photoactive semiconductor material within the pores.

19. The method of claim 18, wherein forming a plurality of particles each comprising a photoactive semiconductor material within the pores comprises forming a plurality of particles each comprising a chalcopyrite material within the pores.

20. The method of claim 19, wherein forming a plurality of particles each comprising a chalcopyrite material within the pores comprises forming a plurality of particles each comprising a multinary chalcopyrite material within the pores.

21. A photoactive device, comprising:
a solid porous ceramic material exhibiting an electrical resistivity of less than about 10 ohm-cm; and
a plurality of particles within pores of the solid porous ceramic material, each particle comprising a photoactive semiconductor material.

22. The photoactive device of claim 21, wherein the solid porous ceramic material has an electrical resistivity of less than about 1 ohm-cm.

23. The photoactive device of claim 22, wherein the solid porous ceramic material comprises at least one of titanium oxide, magnesium oxide, zinc oxide, indium sulfide, indium selenide, molybdenum oxide, tin oxide, zinc sulfide, cadmium sulfide, zinc selenide, and cadmium selenide.

24. The photoactive device of claim 23, wherein the solid porous ceramic material comprises anatase phase titanium dioxide.

25. The photoactive device of claim 24, wherein the anatase phase titanium dioxide comprises macroporous anatase phase titanium dioxide.

26. The photoactive device of claim 21, wherein the solid porous ceramic material comprises macroporous ceramic material.

27. The photoactive device of claim 21, wherein the solid porous ceramic material comprises a layer of the solid porous ceramic material having an average total layer thickness of between about 10 nm and about 500 μm.

28. The photoactive device of claim 21, wherein the solid porous ceramic material comprises anatase phase ceramic material.

29. The photoactive device of claim 21, wherein the photoactive semiconductor material comprises a chalcopyrite material within the pores.

30. The photoactive device of claim 29, wherein the chalcopyrite material comprises a multinary chalcopyrite material.

31. The photoactive device of claim 21, wherein the solid porous ceramic material comprises a solid ceramic phase continuous in three dimensions.

32. The photoactive device of claim 31, wherein pores of the solid porous ceramic material comprise an open pore network continuous in three dimensions.
